(19) United States
(12) Patent Application Publication
(10) Pub. No.: US 2006/0046403 A1
(43) Pub. Date: Mar. 2, 2006

(54) Method of forming separated charge-holding regions in a semiconductor device

(75) Inventors: Wen-Ting Chu, Kaohsiung County (TW); Chia-Ta Hsieh, Tainan (TW); Hung-Cheng Sung, Hsinchu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/931,547

(22) Filed: Aug. 31, 2004

(51) Int. Cl. H01L 21/336; H01L 21/8234; H01L 21/3205

(52) U.S. Cl. 438/288; 438/197; 438/585; 438/287; 438/591

(57) ABSTRACT

A method of forming a semiconductor device comprises forming a gate dielectric layer and a gate electrode over the gate dielectric layer on a semiconductor substrate, partially removing the gate dielectric layer to form two recesses separated by the gate dielectric layer and disposed substantially under the gate electrode, and substantially filling the two recesses with an oxide layer and a material layer to form two separated regions operable to each hold an electrical charge.

### BACKGROUND

A silicon-oxide-nitride-oxide-silicon (SONOS) memory device may use a silicon nitride layer to trap electrical charges in different locations for storing multiple bits of data. For example, one memory cell may use the left position of the silicon nitride layer to store one bit and the right position of the silicon nitride layer to store a second bit (referred to as a 2-bit cell). In high temperature environment, the electrical charges trapped in the left position and the electrical charges trapped in the right position may diffuse and merge together and lead to data retention failures. Such failures may become serious when a 2-bit cell SONOS memory device is scaled down to achieve a small gate length.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart of a method to form separated silicon nitride regions; and

FIGS. 2a through 2e are simplified sectional views of a semiconductor device at selected stages of manufacture.

### DETAILED DESCRIPTION

The present disclosure relates generally to a semiconductor device and, more specifically, to a semiconductor device having separated charge-holding regions.

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

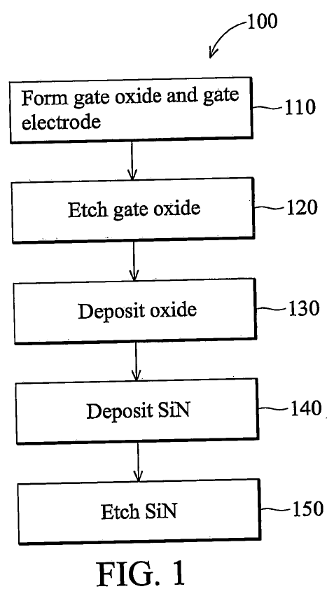

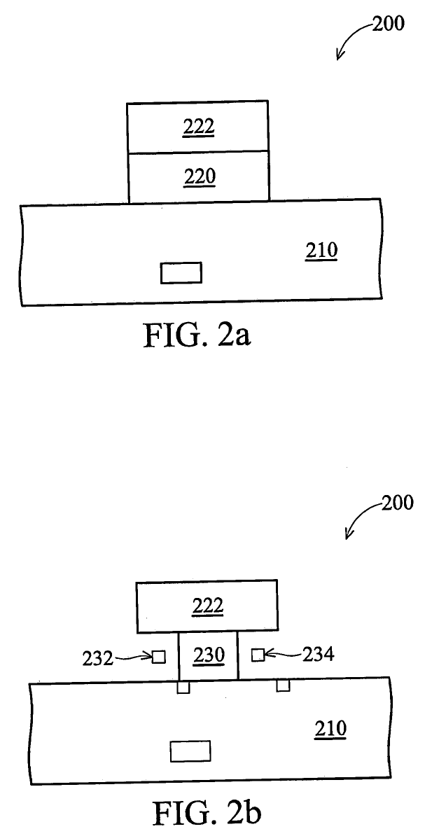

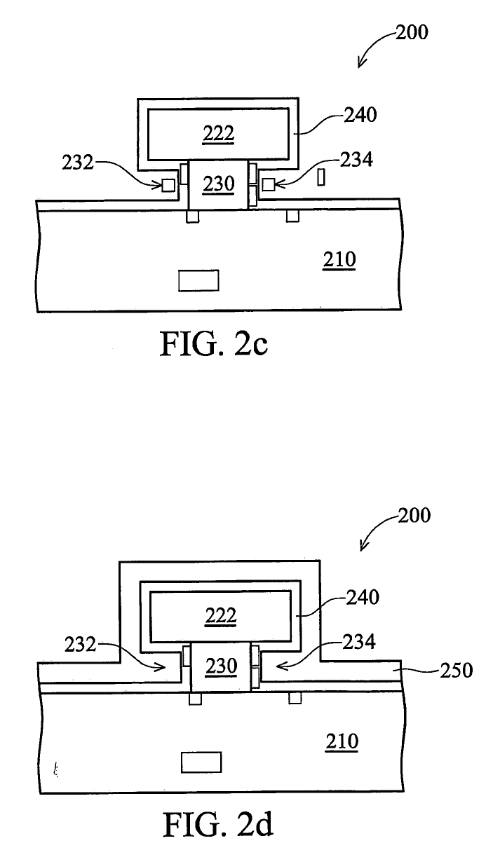

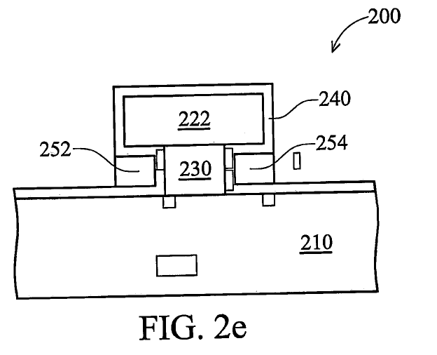

FIG. 1 is a flowchart of an embodiment of a method 100 for forming a semiconductor device having separated silicon nitride regions. FIGS. 2a through 2d, as additional reference, are simplified sectional views of a semiconductor device 200 at selected states of manufacture to illustrate an embodiment of the method 100 of making the device 200.

Provided with a semiconductor substrate 210 as shown in FIG. 2a, the method 100 begins at step 110 by forming a stacked gate structure including a gate silicon oxide feature (gate oxide) 220 and a gate electrode feature 222 on the semiconductor substrate 210, wherein the gate electrode feature 222 is overlying the gate oxide 220.

The gate oxide 220 may have a thickness ranging from about 100 Angstroms to about 500 Angstroms. An exemplary thickness may be about 200 Angstroms. The gate oxide 220 may be deposited using a process including thermal oxidation, chemical vapor deposition (CVD), or a combination thereof.

The gate electrode feature 222 may comprise polycrystalline silicon (gate poly). The gate electrode 222 may further comprise metal silicide. The gate poly may be deposited by a process including CVD and physical vapor deposition (PVD). In one embodiment, the gate electrode 222 may comprise metal such as copper, aluminum, tungsten, titanium, tantalum, or a combination thereof. The metal material may be formed or deposited by a process including CVD, PVD, atomic layer deposition (ALD) and plating. In another embodiment, the gate electrode may have a multilayer structure and comprise both poly silicon and metal materials.

In step 120 of the method 100 and with additional reference to FIG. 2b, the gate oxide 220 may be etched to form an etched gate oxide 230 having two recessed regions 232 and 234. The two recessed regions may have recessed depths ranging from about 50 Angstrom to about 500 Angstrom. An exemplary etching process to form the two recessed regions comprises wet etching using hydrofluoric acid (HF).

In step 130 and with additional reference to FIG. 2c, a thin layer of silicon oxide 240 may be formed at least on the top surface of the substrate 210 and on the bottom surface of the gate electrode 222. Methods to form the silicon oxide may include thermal oxidation and CVD. For example, if the gate electrode comprise poly silicon, thermal oxidation may be used to form silicon oxide on both the top surface of the substrate 210 and the bottom surface of the gate electrode 222. The thickness of the silicon oxide 240 may have a range between about 20 Angstrom and about 150 Angstrom. Other suitable dielectric materials may be used in place of silicon oxide.

In step 140 and with additional reference to FIG. 2d, a silicon nitride layer 250 may be formed and substantially fill the two recessed regions 232 and 234. Methods to form the material layer may include CVD such as low pressure CVD (LPCVD), high density plasma CVD (HDPCVD), and plasma enhanced CVD (PECVD). The silicon nitride layer 250 may be thicker than the two recessed regions to ensure substantially filling of the two recessed regions. For example, the silicon nitride may be formed by reacting dichlorosilane (SiCl₂H₂) and ammonia (NH₃) at a temperature between about 700° C. and about 800° C.

In step 150 and with additional reference to FIG. 2e, the silicon nitride layer 250 may be further etched to partially remove the silicon nitride layer 250 in the areas outside of the two recessed regions 232 and 234 to form two separated charge-holding regions 252 and 254. Dry etching or other suitable anisotropical removing process may be used to partially remove the silicon nitride layer 250. In one example, partial removal of the silicon nitride may be implemented by dry etching using a fluorine-based etchant such as carbon fluorine and oxygen (CF₄—O₂).

In embodiments in which the semiconductor device 200 is employed for flash memory applications, the two separated charge-holding regions 252 and 254 may be employed to trap electrical charges and store two separate data bits. Therefore, two bits of data may be stored in one memory cell. Since these two charge-holding regions 252 and 254 are separated by the gate oxide 230, diffusion and merging of the trapped electrical charges in the two regions are eliminated. Modifications of the above-described method may be made to make a device operable to hold more than two electrical charges.

The semiconductor device 200 may comprise a silicon-oxide-nitride-oxide-silicon (SONOS) memory cell. Alternatively, the semiconductor device 200 may comprise a metal-oxide-nitride-oxide-silicon (MONOS) memory cell wherein the gate electrode comprises metal material as described in step 110.

In other embodiment, the silicon nitride layer 250 may be replaced by other materials such as polycrystalline silicon. Polycrystalline silicon may be deposited and dry etched to form two separated polycrystalline silicon regions. Charges may be stored in the two separated poly regions and be electrically separated by the gate oxide 230. Such formed a device may have a structure of silicon-oxide-silicon-oxide-silicon (SOSOS) or metal-oxide-silicon-oxide-silicon (MOSOS). In another example, the silicon nitride layer 250 may have multi-layer structure and further comprise other materials such as high dielectric constant (k) material, e.g., k>4.0. The high k material and silicon nitride may be sequentially deposited and substantially fill the two recessed regions 232 and 234, for example. Dry etching or other suitable methods may be used to partially remove the deposited high k material and silicon nitride and form two separated regions each having silicon nitride and high k material. Alternatively, the gate oxide 220 may be replaced by or further comprise other suitable dielectric material and may also have multilayer structure.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

What is claimed is:

1. A method of forming a semiconductor device comprising:
forming a gate dielectric layer and a gate electrode over the gate dielectric layer on a semiconductor substrate;
partially removing the gate dielectric layer to form two recesses separated by the gate dielectric layer and disposed substantially under the gate electrode; and
substantially filling the two recesses with an oxide layer and a material layer to form two separated regions operable to each hold an electrical charge.

2. The method of claim 1, wherein substantially filling the two recesses comprises:
forming an oxide layer to at least partially fill the two separate recesses;
forming a material layer to substantially fill the two separate recesses; and
partially removing the material layer to form the two separated charge-holding regions.

3. The method of claim 1, wherein forming a gate dielectric layer comprises forming a silicon oxide layer.

4. The method of claim 1, wherein forming a gate electrode comprises depositing and patterning polycrystalline silicon.

5. The method of claim 1, wherein forming a gate electrode comprises depositing and patterning a metal.

6. The method of claim 1, wherein partially removing the gate dielectric layer comprises wet etching the gate dielectric layer.

7. The method of claim 1, wherein partially removing the gate dielectric layer to form two recesses comprises forming recesses each having a depth of about 50 to 500 Angstroms.

8. The method of claim 2, wherein forming an oxide layer comprises forming a silicon oxide layer using thermal oxidation.

9. The method of claim 2, wherein forming an oxide layer comprises forming a silicon oxide layer using a CVD process.

10. The method of claim 2, wherein forming a material layer comprises forming a silicon nitride using a CVD process.

11. The method of claim 2, wherein forming a material layer comprises forming a polycrystalline silicon layer.

12. The method of claim 2, wherein forming a material layer comprises forming a dielectric layer with a dielectric constant greater than 4.

13. The method of claim 2, wherein forming a material layer comprises forming a multi-layer structure.

14. The method of claim 2, wherein partially removing the material layer comprises dry etching the material layer.

15. The method of claim 1, wherein the method of forming a semiconductor device comprises forming a silicon-oxide-nitride-oxide-silicon (SONOS) memory device or a metal-oxide-nitride-oxide-silicon (MONOS) memory device.

16. A method of forming a multi-bit memory device comprising:
forming a gate dielectric layer and a gate electrode over the gate dielectric layer on a semiconductor substrate;
partially removing the gate dielectric layer to form two separated recesses therein disposed substantially under the gate electrode;
forming a silicon oxide layer to at least partially fill the two separate recesses;
forming a silicon nitride layer to substantially fill the two separate recesses; and
partially removing the silicon nitride layer to form the two separated charge-holding regions.

17. The method of claim 16, wherein partially removing the gate dielectric layer to form two recessed comprises forming recesses each having a depth of about 50 to about 500 Angstroms.

18. A multi-bit memory device comprising:
a substrate;
a gate electrode disposed over a multi-bit charge-holding structure, the multi-bit charge-holding structure comprising at least two charge-holding regions separated by a dielectric structure, the multi-bit charge-holding structure formed by:
forming a gate dielectric layer and the gate electrode over the gate dielectric layer on a semiconductor substrate;
partially removing the gate dielectric layer to form at least two recesses separated by the gate dielectric layer and disposed substantially under the gate electrode; and
substantially filling the two recesses with an oxide layer and a material layer to form at least two separated regions operable to each hold an electrical charge.

19. The memory device of claim 18, wherein substantially filling the at least two recesses comprises:
forming an oxide layer to at least partially fill the at least two separate recesses;
forming a nitride layer to substantially fill the at least two separate recesses; and
partially removing the nitride layer to form the at least two separated charge-holding regions.

20. A memory device comprising:
a substrate;
a gate dielectric layer overlying the substrate;
a gate electrode overlying the gate dielectric layer, wherein at least two recesses are separated by the gate dielectric layer and disposed substantially under the gate electrode;
an oxide layer at least partially filling the at least two separate recesses; and
a material layer overlying the oxide layer and filling the at least two separate recesses, wherein the oxide layer and the material layer in the at least two separate recesses serve as at least two separated charge-holding regions.

21. The memory device of claim 20, wherein the material layer comprises a silicon nitride layer.

22. The memory device of claim 20, wherein the material layer comprises a polycrystalline silicon layer.

23. The memory device of claim 20, wherein the material layer comprises a dielectric layer with a dielectric constant greater than 4.

24. The memory device of claim 20, wherein the material layer comprises a multi-layer structure.

25. The memory device of claim 20, wherein each of the at least two recesses comprises a depth of about 50 to about 500 Angstroms.

26. The memory device of claim 20, wherein the multi-bit memory device comprises a silicon-oxide-nitride-oxide-silicon (SONOS) memory device or a metal-oxide-nitride-oxide-silicon (SONOS) memory device.
